(19) United States
(12) Patent Application Publication
(10) Pub. No.: US 2025/0258241 A1
(43) Pub. Date: Aug. 14, 2025

(54) METHODS OF FORECASTING BATTERY STATE OF HEALTH

(71) Applicant: Garrett Transportation I Inc., Torrance, CA (US)

(72) Inventor: Tomas Poloni, Malinovo (SK)

(73) Assignee: Garrett Transportation I Inc., Torrance, CA (US)

(21) Appl. No.: 18/436,830

(22) Filed: Feb. 8, 2024

(51) Int. Cl. G01R 31/392; B60L 50/60; B60L 58/12; B60L 58/16; G01R 31/367; G01R 31/382

(52) U.S. Cl. CPC G01R 31/392; B60L 50/60; B60L 58/12; B60L 58/16; G01R 31/367; G01R 31/382; B60L 2250/00

(57) ABSTRACT

Methods and systems for estimating remaining time to end-of-life of a rechargeable battery used in vehicle or grid application. A degradation filter is used to construct estimated battery capacity values from a series of battery capacity measurements. An inverted degradation model calculates a first time to end-of-life using parameters determined by the degradation filter. A cubic-end-point model calculates a second time to end-of-life using a set of coefficients derived from the series of battery capacity measurements. A decision logic identifies one the first time to end-of-life or the second time to end-of-life as reliable.

### BACKGROUND

Lithium ion batteries are increasingly playing a pivotal role in applications ranging from transport to grid energy storage. Such batteries age and degrade over time and with usage, and understanding of such degradation is limited. To ensure adequate capacity over intended life, and to avoid unsafe operation conditions, lithium ion batteries are often oversized and under used, creating cost inefficiencies.

Second life applications offer a potential means of offsetting high initial battery costs in electric vehicle (EV) applications. However, second life applications rely on accurate capacity forecasting, which determines the potential value of a cell in its secondary application. Hence, accurate prognostics is an important component of a modern battery management system. Since the performance capability of a cell is largely defined by its nominal capacity and internal resistance, the State of Health (SOH) is typically defined by one or both of these parameters. Predicting the state of a lithium ion battery is non-trivial due to the complex interplay of parameters and the path dependence of the degradation behavior.

New and alternative methods and systems for analysis of battery state of health are desired.

### OVERVIEW

The present inventors have recognized, among other things, that a problem to be solved is the need for new and alternative methods and systems for analysis of battery state of health, and prediction of battery end-of-life.

A first illustrative and non-limiting example takes the form of a method of estimating time to end of life (EOL) for a battery, comprising: obtaining a plurality of state of charge measurements and current measurements from the battery over a plurality of time points; estimating battery capacity at each of the plurality of time points; applying a first model of battery capacity to generate a first set of battery capacity estimates, and estimating a first time to EOL from the first model; applying a second model of battery capacity to generate a second set of battery capacity estimates, and estimating a second time to EOL from the second model; and selecting the estimated time to EOL from the first time to EOL and the second time to EOL by determining which of the first set of battery capacity estimates and the second set of battery capacity estimates is more accurate, using the estimated battery capacity for at least one of the time points.

Additionally or alternatively, each of the first model and the second model are adaptive models. Additionally or alternatively, each of the first model and the second model uses a best fit analysis relative to the estimated battery capacity at each of the plurality of time points. Additionally or alternatively, the first model is an inverted degradation filter in which the battery capacity is directly proportional to a square root of time. Additionally or alternatively, the second model is a cubic endpoint model in which the battery capacity is determined from a cubic polynomial using time.

Additionally or alternatively, the step of selecting the estimated time to EOL is performed by: determining a first error associated with the first model and a second error associated with the second model; and identifying the first set of battery capacity estimates as more accurate unless the second error is less than the first error.

Additionally or alternatively, the method also includes using an adaptive model including each of time from first use of the battery, the plurality of battery capacity measurements, and filter parameters to generate each of a gain parameter for the inverted degradation filter, a break-in parameter for the inverted degradation filter, and a plurality of battery capacity estimates; wherein the step of applying a first model of battery capacity uses the plurality of battery capacity estimates, and wherein the step of applying a second model of battery capacity uses the plurality of battery capacity estimates.

Additionally or alternatively, the method also includes storing data for the first model and the second model as stored data, and associating the stored data with the battery for use in determining a resell price for the battery. Additionally or alternatively, the first model is a nominal performance model, and the second model is a failing device model, and the step of selecting the estimated time to EOL includes determining that the second model is more accurate, further comprising issuing an alert to a user of the battery in response to determining that the second model is more accurate.

Another illustrative and non-limiting example takes the form of a method of estimating time to end of life (EOL) for a battery, comprising: obtaining a plurality of state of charge and current usage estimates to determine a plurality of battery capacity measurements; applying an on-board degradation filter using an adaptive model including each of time from first use of the battery, the plurality of battery capacity measurements, and filter parameters to generate each of a gain parameter, a break-in parameter, and a plurality of battery capacity estimates; applying an inverted degradation filter to estimate a first time to EOL using the gain parameter and the break-in parameter; applying a cubic end point model to estimate a second time to EOL using the plurality of battery capacity estimates or the plurality of battery capacity measurements; selecting between the first time to EOL and the second time to EOL using a decision logic.

Additionally or alternatively, the method further includes pre-iterating the on-board degradation filter and adaptive model using data from a digital twin by: reporting the plurality of battery capacity estimates to a server maintaining the digital twin; receiving estimates of the break-in parameter and the gain parameter from the digital twin; and determining a correlation matrix for use in the adaptive model from the received estimates of the break-in parameter and the gain parameter from the digital twin.

Still further illustrative and non-limiting examples include vehicles comprising a motor generator unit (MGU) for providing motive power to the vehicle, a rechargeable battery configured to provide electric power to the MGU, and a configurable controller adapted to perform a method of estimating time to end of life (EOL) for a battery by use of any of the preceding methods. Additional illustrative and non-limiting examples take the form of configurable controllers which are configured to perform any of the preceding methods. The vehicle and/or the configurable controller may comprise a non-transitory memory that is controller readable encoding controller executable instructions for performing any of the above methods, or the methods described in the detailed description.

This overview is intended to introduce the subject of the present patent application. It is not intended to provide an exclusive or exhaustive discussion. The detailed description provides examples and further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 shows an illustrative system in a functional block diagram;

FIG. 2 shows battery capacity loss over time;

FIG. 3 illustrates a battery model along with interaction with a test system;

FIG. 4 shows an illustrative vehicle in functional block form;

FIGS. 5-6 show illustrative battery installations;

FIG. 7 is a block flow diagram for an example method; and

FIGS. 8A-8C illustrate adaptive modelling and operation of a decision logic.

### DETAILED DESCRIPTION

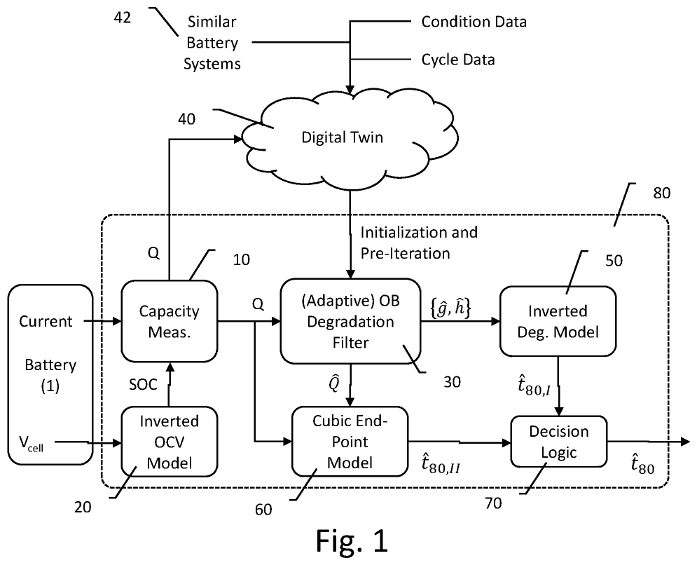

FIG. 1 shows an illustrative system in a functional block diagram. A battery 1 is to be modeled and characterized in a controller 80. The controller 80 is shown having a number of functional blocks. The controller 80 may take many forms, including, for example, a microcontroller or microprocessor, coupled to a memory storing readable instructions for performing methods as described herein, as well as providing configuration of the controller for the various examples that follow. The controller may include one more application-specific integrated circuits (ASIC) to provide additional or specialized functionality, such as, without limitation a signal processing ASIC that can filter received signals from one or more sensors using digital filtering techniques. Logic circuitry, state machines, and discrete or integrated circuit components may be included as well. The skilled person will recognize many different hardware implementations are available for a controller. The digital twin 40 may be in the form of a set of stored executable instructions on a computer or server, separate from the controller 80.

The controller obtains an open circuit voltage (OCV), which may be a cell, pack, or battery sub-system (having one or more cells of the battery or battery pack) voltage, shown illustratively as V_{cell}, and applies an inverted open-circuit-voltage model at 20 to obtain an estimated state of charge (SOC) on the battery. As used in the following, the “battery” may be any of an entire battery pack, a single battery cell, or a battery subcircuit comprising a plurality of battery cells but not the entire battery pack, as desired. Current flows in and out of the battery are tracked at a capacity measurement block 10, which also receives the estimated SOC. Using changes in battery OCV and knowledge of current flow into and out of the battery cell, pack or subsystem, the battery capacity, Q is estimated in an iterative or repeated manner.

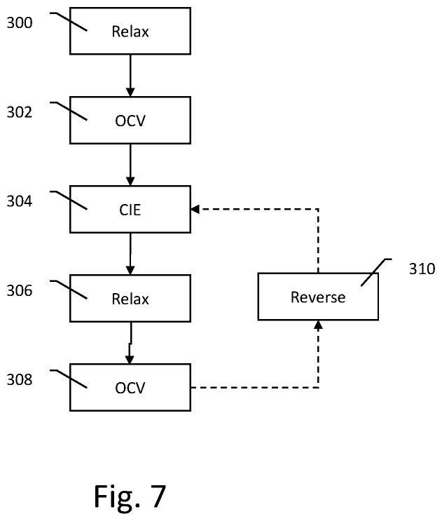

For example, the battery OCV can be measured during and/or after a period of relaxation of the battery, with no or minimal battery current for a period of time. Current flow over time is then monitored and summed. Current flow is stopped, and the battery OCV is again measured after a period of relaxation. A stored battery model can be referenced to use the first and second OCV measurements and the accumulated current flows to then estimate battery capacity, Q. FIG. 7, below, shows an illustrative method. At a high level, the accumulated current flow is proportional to the capacity times the change in battery OCV, similar to an ideal capacitor.

The battery capacity represents the quantity of charge that the battery can hold when recharged to its full extent. Various chemical reactions in the battery/battery cell are partially irreversible, and as time accumulates, the battery capacity fades due to various factors, including breakdown of electrolyte, lithium plating and solid electrolyte interphase phenomena. Different factors can cause one or another of these factors to have greater effects; for example, higher temperatures are associated with SEI growth, and lower temperature are associated with lithium plating.

An adaptive on-board (OB) degradation filter is used at 30 to receive a series of values for Q, where Q is recalculated with each charge integration event (CEI). A CEI can be any period in which charge/current is drawn from or delivered to the battery, with available OCV measurements before and after the period of current draw/delivery. For accuracy, the OCV measurements may preferably be obtained after a relaxation period for the battery; the duration of a relaxation period needed can vary with battery type and design, and may be on the range of tens of seconds to tens of minutes.

Two end-point models are then calculated. A first endpoint model uses the OB Degradation Filter 30 to estimate two variables, {ĝ, ĥ} provided to an inverted degradation model at 50 to estimate a first end-of-life (EOL) time, denoted as \hat{t}_{80,1}, which is provided to a decision logic 70. A second endpoint model takes the form of a cubic-end-point model is used at 60 to estimate a second EOL time, denoted as \hat{t}_{80,11}, which is also provided to the decision logic 70. The decision logic 70 determines a final EOL estimate, \hat{t}₈₀.

The inverted degradation model 50 is operable to estimate end of life based on non-failing performance, that is, performance in accordance with expected or modeled behavior. The cubic end-point model, on the other hand, models an endpoint for a battery that has failed to deliver full life, which may occur for many reasons including internal failures (quality issues) or usage that shortens life, such as high current charging or discharging at non-ideal or poorly controlled temperatures.

Each model is built based on the performance of the battery 1, and adapts to continuously updated measurements. The inverted degradation model 50 is constructed assuming a more gradual reduction in battery capacity over its lifetime, corresponding to behavior of a non-failing device, though still tailored to the actual battery performance. In other examples, a static model could be used, if desired, in place of the inverted degradation model 50, based for example on testing of batteries in a controlled environment or other observational data for other batteries sharing characteristics with (often identical to) the battery 1. The cubic end-point model is selected to track battery performance indicative of a battery that is failing to meet expected end-of-life or replacement indicator performance, and adjusts its projections quickly to a battery failure. The cubic form used is selected because it provides an S-shaped curve over time, with initial relatively steep reduction in battery capacity associated with battery break-in periods/early life, a flattened period of useful life, and another relatively steeper drop-off of capacity as the battery fails.

The variables, {ĝ, ĥ}, provided to the inverted degradation model 50 are based on the degradation model of a structure, according to Formula 1:

$$y = g \sqrt{t} + h \qquad \{ 1 \}$$

Where y is the capacity, t is the time interval from beginning of life, in appropriate units, g is a gain parameter (and is negative so that capacity reduces as time advances), and h is the absolute term used as a break-in parameter. With each new reported Q going to the OB Degradation Filter 30, an estimation algorithm is used to estimate and update the parameters, g and h, using, for example, on-line least squares algorithm, or a Kalman filter. If time/sampling intervals for Q are irregular, a hybrid Kalman filter may be used if desired.

The inverted degradation model at 50 may use the rearranged expression of FIG. 1 shown in Formula 2:

$${t}_{80 , I} = {( {y}_{80} / g - h / g )}^{2} \qquad \{ 2 \}$$

Throughout this example, the subscript 80 is used to indicate that an 80% remaining useful capacity is being used as the EOL point; other EOL points may be used, as desired. Thus, y₈₀ is the capacity value for the battery at 80% of nominal.

To aid with accuracy and predictability, as well as to aid in identifying any break-out from the “normal” model, the degradation filter may be pre-iterated using a digital twin (DT) simulation obtained from the cloud, as indicated at 40. The DT simulation is generated using “similar” systems, including similar battery system data 42. A battery system may be similar if the construction thereof is identical or similar (size, chemistry, layout, etc.), as well as based on, for example, similarity of conditions of operation (i.e., subject to similar environmental conditions, or subjected to similar cycling). Here, the underlying battery may be in an EV, in which case cycle data (usage) may predominate any similarity assessment, or a fixed installation lacking climate controls (i.e. utility based structures) in a given geography/region, so that each battery has similar temperature conditions over time. A combination of usage and environmental conditions can be tracked for similarity determinations as well. Further, there may be for each battery a system of scoring or otherwise tracking usage conditions, such as a matrix of current load and battery temperature history with cells for each of a plurality of combinations, allowing comparison based on prior usage and conditions. Other “similarity” tests can be used as desired. While the digital twin pre-populates data based on other batteries or a stored model, in the illustrative example, the filter 30, and resultant inverted degradation model 50 are adaptive to the performance of battery 1.

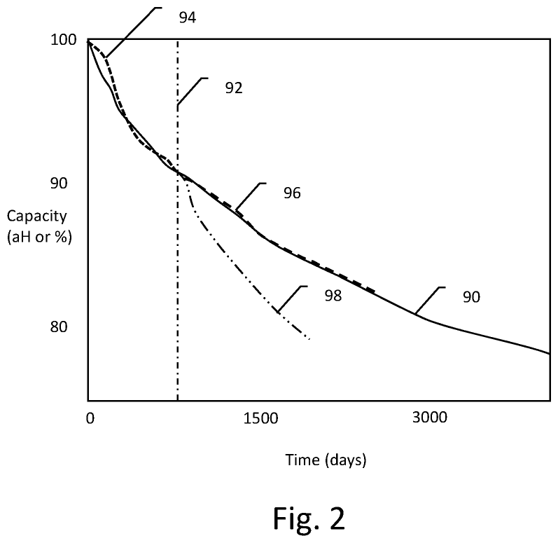

FIG. 2 shows battery capacity loss over time. The battery degradation occurs over time, thus the horizontal axis shows time (in days in this example), and the vertical axis shows battery capacity, which can be understood in absolute terms (such as amp-hours, Ah), or relative terms (percentage, %). The graph illustrates a vertical line at 92 which can be understood as a break-in period during early life of the battery. From t=0 to line 92, the measurements can vary and convergence of the analysis is not expected yet. The calculated battery capacity is shown in heavier broken line 94. Tracking to the nominal degradation line 90 before the end of the break-in period 92 is not particularly close. After the end of the break-in period 92, performance of two batteries is shown relative to nominal line 90. A convergence or healthy battery performance is shown at 96, tracking closely to line 90 over time. A divergent line, however, is shown at 98. This battery, for one reason or another, has a significantly shorter total life, and drops in capacity much quicker than the healthy performance 96. Usage or quality issues may cause such a divergence; the purpose here is not necessarily to identify the root cause, but instead to identify the battery with shortened time to EOL.

Returning to FIG. 1, the initialization and pre-iteration may be used during the break in period to enhance accuracy of {ĝ, ĥ}, which are subject to noise during the break-in period. Such pre-iteration may consider usage patterns and/or environmental factors for other batteries when determining which data to rely upon. The inverted degradation model at 50 is used to estimate the time to EOL reported to the Decision Logic 70.

The pre-iteration using cloud or other external data may continue until either a set period of time has passed, a set quantity of usage has occurred, a set level of remaining capacity is estimate, or until the onboard system data converges. For example, the analysis used in the OB degradation filter 30 may generate both model parameters and a covariance matrix. Once the covariance matrix illustrates convergence to a degree that satisfies one or more pre-set conditions, the use of the external data may cease, and the onboard data is used exclusively for continuing updates of the parameters {ĝ, ĥ}, if desired.

The cubic end point model 60 is used for identifying a potential break-out scenario, as the degradation filter may be unable to converge and learn new parameters quickly enough to provide an accurate model in the event of a break-out. A cubic end-point model is one example of a model that may be used with the aim of providing a faster response than the inverted degradation model. In an example, Formula 3 may be used:

$$y = {ax}^{3} + {bx}^{2} + cx + d \qquad \{ 3 \}$$

Where y is the capacity, x is the time interval (for example, in days), and a, b, c, and d are fitted parameters that match the data. That is, each time Q is updated and provided to 60, the cubic end-point model can assess the values for a, b, c, and d that best fit the series of reported Q values.

Some examples of the cubic end-point model 60 may instead use an estimated version of Q, that is, \hat{Q}, as shown in FIG. 1, obtained from the adaptive OB degradation filter 30. The estimated capacity can be derived by solving a linear estimation problem through a receding window of measured Q values, whether from drive or other usage cycles, or obtained by charge/discharge testing, both explained below relative to FIG. 7. Thus Formula 4 may be used:

$$[ \begin{matrix}- {\sum }_{k = {k}_{1}}^{{k}_{2}} {η}_{k} {i}_{k} \\ - {\sum }_{k = {k}_{2}}^{{k}_{3}} {η}_{k} {i}_{k} \\ ⋮ \\ ⋮\end{matrix} ] = Q [ \begin{matrix}{z}_{k 2} - {z}_{k 1} \\ {z}_{k 3} - {z}_{k 2} \\ ⋮\end{matrix} ] \qquad \{ 4 \}$$

Where ηₖ is the battery charging/discharging efficiency, each kᵢ is a time instance, each iₖ, represents a current applicable during the time instance (the equation assumes current is always the same but that need not be the case), and each z is an estimate of SOC, which can be obtained using an inverted SOC/OCV model, at the noted time instance.

The digital twin in FIG. 1 may simulate capacity loss degradation over time based on environmental conditions and reported usage. For example, a capacity loss coefficient can be calculated as a product of terms representing SOC dependence and battery temperature dependence, for example, using Formula 5:

$$- {Coeff}_{aging} ( SOC , {T}_{batt} ) = ( {a}_{2} {SOC}^{2} + {a}_{1} SOC + {a}_{0} ) \cdot exp ( \frac{{E}_{a}}{Rt} [ \frac{1}{{T}_{o} + {T}_{ref}} - \frac{1}{{T}_{0} + {T}_{batt}} ] ) \qquad \{ 5 \}$$

Here, parameters a₀, a₁, a₂, Eₐ, and T_{ref} are each calibrated for the battery under consideration using, for example, bench and/or destructive test data and/or population-based data. Rt is the gas constant and T₀ is 273.15 K (0 degrees C.).

The relative capacity variation can be determined from Formula 6:

$$Q ( {t}_{i + 1} ) = Q ( {t}_{i} ) + \frac{1}{2} {Coeff}_{aging} ( SOC ( {t}_{I + 1} ) , {T}_{Batt} ( {t}_{i + 1} ) ) \frac{{t}_{i + 1} - {t}_{i}}{\sqrt{{t}_{i + 1} + time\_offset}} \qquad \{ 6 \}$$

Where Formula 6 represents the simulated typical capacity loss degradation evolution as influenced by temperature in the given geographic area, using the time offset between production of the battery pack, cell or subcircuit and the beginning of the testing/analysis, t is the time elapsed since the beginning of testing, SOC is the state of charge scaled to a value in the interval [0,1], and Q(tᵢ) is the relative capacity at the time step, tᵢ.

The digital twin can use Formulas 5 and 6 to generate a nominal capacity fade trajectory for use in the OB Degradation Filter 30. A random number, r, having a normal distribution in the interval [0,1] is used to create a distribution of random changes in SOC values for a set of n drive cycles, using a model as shown in Formula 7:

$$x = 2 * r * {x}_{max} - {x}_{max} \qquad \{ 7 \}$$

Where xₘₐₓ is a limiting or maximum change in SOC. A set of y data is generated using the relationship y=Q*x, and an integrated current noise is added to the y data based on expected drive cycle or operation cycle duration statistics. In addition, the change in SOC noise is added to the set of x data. Any of weighted least-squares, weighted total least squares, or adaptive weighted total least-squares methods are then used to generate the capacity estimates, where the choice of which least squares algorithm to use in the Digital Twin should be the same as the choice for the OB Capacity Measurement 10. These sets of data are then used in the degradation filter in its pre-iteration phase to gain convergence and provide both a converged set of parameters and the error covariance matrix for use after the pre-iteration phase is completed.

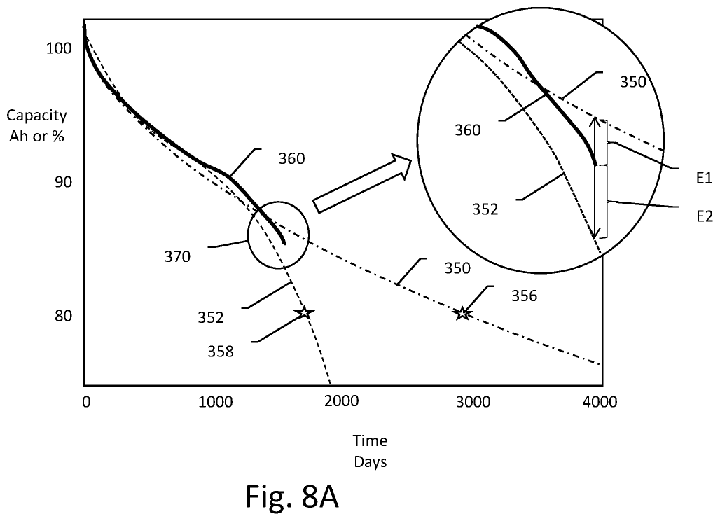

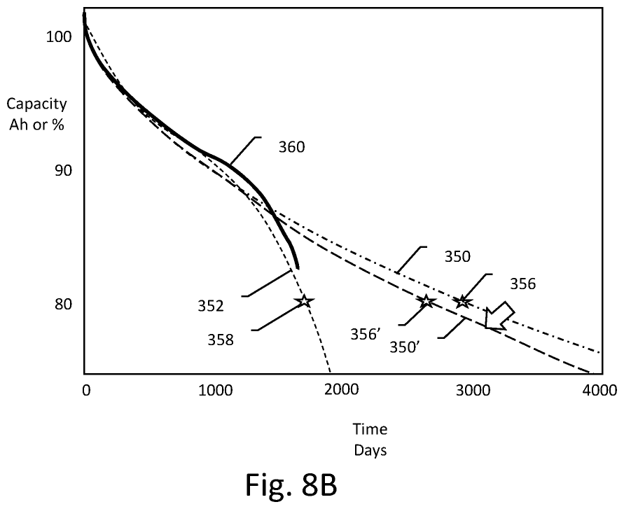

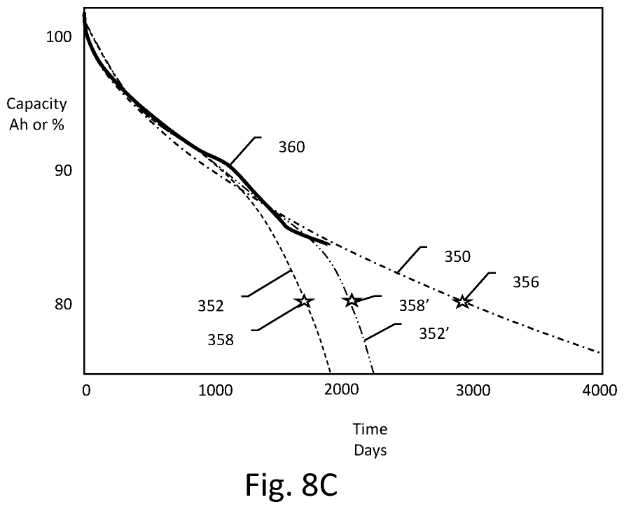

The decision logic 70 monitors the error between capacity data and the Inverted Degradation Model (IDM) (error E1), and the error between the capacity data and the cubit model (error E2). Either of E1 or E2 may take several forms, including an integral, forgetting integral, smoothed updating function, etc. as desired. If the decision logic 70 finds that E1 is less than or approximately equal to E2, the system relies on the IDM to model the battery capacity. If E2 is less than E1, then the cubic model is relied upon instead. If desired, the boundary between one or the other of the models controlling or being relied upon may use a tunable threshold or error bound. If switching between models is a concern, a hysteresis may be built in as well. FIGS. 8A-8C, illustrate the adaptive models, and also show how a decision logic 70 operates in an example. Other methods, also discussed relative to FIGS. 8A-8C, may be used instead.

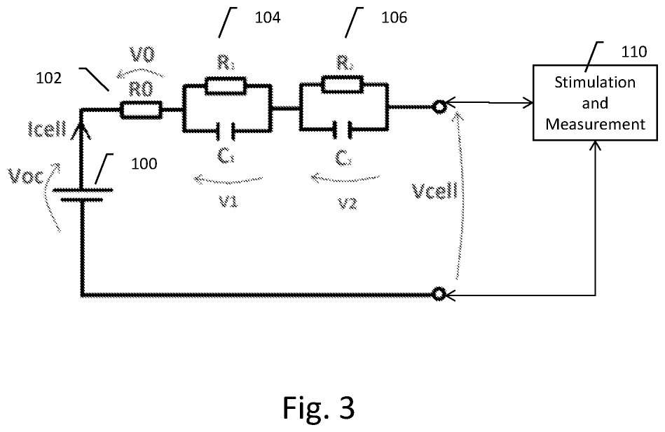

FIG. 3 illustrates a battery model along with interaction with a test system. Here a second order battery model is used, with an OC voltage at 100, an internal resistance R₀ at 100, two RC circuits 104, 106, each of which may represent impedance mechanisms in the battery cell, with cell voltage, V_{cell}, being the terminal voltage. In some examples, a stimulation and measurement block 110 is provided to provide onboard diagnostic data and tests. Block 110 may include an onboard electrochemical impedance spectroscopy circuit. For example, details of an onboard EIS system, as well as additional or alternative designs, are disclosed in U.S. patent application Ser. No. 18/498,996, filed Oct. 31, 2023, titled SYSTEM AND METHOD FOR ONLINE ELECTROCHEMICAL IMPEDANCE SPECTROSCOPY MEASUREMENT IN A BATTERY, the disclosure of which is incorporated herein by reference. That system or other EIS systems may be used in the examples herein to both generate an excitation signal and measure outputs, as desired.

In some examples, rather than, or in addition to, using macro-level battery charging and discharging operations to populate data for the capacity estimation, test modes may be used. For example, with the battery in a relaxed state (that is, after a period of non-use or no current flow), the battery V_{oc} 100 is measured. Next, a known quantity of current/charge can be delivered to the battery from a stimulation and measurement system to charge the battery cell. A sufficient quantity should be delivered to attain desirable signal-to-noise ratio. Next, the battery may be allowed to relax, and one or more voltage measurements, preferably at zero current to provide the V_{oc} 100, are taken. The cycle may then be reversed, if desired, to return the battery to its original state and/or to obtain an additional measurement. The use of an onboard stimulation and measurement block 110 may be helpful to provide regular data for a system that, for example, is only sporadically in use, or where usage/drive cycles are inconsistent, so that any noise introduced by differences in usage/drive cycles can be mitigated.

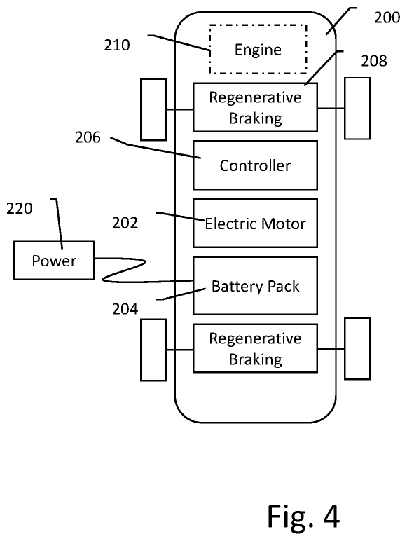

FIG. 4 illustrates a vehicle 200 that can be referred to as an electric vehicle (EV) herein. The EV has an electric motor 202 used to drive the wheels at least some of the time, with power from a battery pack 204. The system may have a controller 206, which may include therein a battery management system (BMS). The BMS may include a stimulation and measurement block 110 as described above in FIG. 3. The controller 206 may include a controller 80 as described above in FIG. 1.

The vehicle may include an engine as indicated at 210, making the EV a hybrid EV as that term is generally used. Alternatively, the vehicle 200 may be a purely electric vehicle, if desired, and 210 may be omitted. Regenerative braking 208 may also be used to obtain and store power in the battery pack 204. The battery pack 204 may be rechargeable using externally obtained power 220, from an external charger or charging station, or by use of an onboard charger that obtains grid or line power, for example.

For a vehicle 200, the battery pack 204 may be monitored using the above methods to predict and identify end of life (EOL). The system may store usage statistics including for example, samples temperature and usage (current) data along with SOC. Tracked estimates of battery capacity may also be stored. Such stored data may be handled onboard or by communication to a remote server with identifying data for the battery pack 204, which may be associated with, for example, a unique identifier such as a serial number. This stored data can be used to determine remaining useful life for the battery pack for a second life usage, for example. Remaining useful life may be used to determine suitability for second life usage, such as for specific installations and/or whether the battery pack 204 can be used at all, as well as pricing for the battery pack 204. For example, if EOL tracks to a nominal case as shown in FIG. 2, this generally suggests that the battery pack 204 can be used in a second life system such as in grid storage, uninterruptable power supply, etc. On the other hand, if the EOL does not track to the nominal case, this may suggest that use in a second life system is inadvisable, or it may limit the availability or lifetime of the battery pack 204 for certain installations. In some examples, a battery pack that does not track to a nominal EOL may be suitable for reconditioning, such as by the use of current cycling to remove Lithium plating, to the extent feasible.

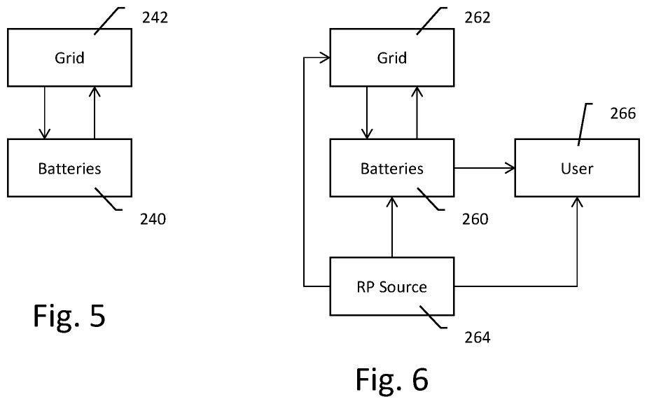

FIGS. 5-6 show illustrative battery installations that may be for primary life or secondary life usage. It is generally expected that EV use in FIG. 4 would be a primary life use of battery packs, as the vehicle context can be highly demanding. FIG. 5 shows use of batteries 240 for grid storage, where the grid 242 may provide electricity at varying rates and demands over time. As is known in the art, grid storage batteries 240 may be useful to alleviate high demand time periods (hot afternoons, for example) by storing power obtained from the grid 242 during low demand or low-cost time periods.

FIG. 6 shows an example that may be used, for example, in a residential or commercial facility where a renewable power (RP) source 264, such a solar panels or wind power, is available. The RP source 264 may be available to meet user needs 266 and or for sale of power to the grid 262. The batteries 260 can be use to time-shift the power, storing excess power from the RP source 264 for use by the user 266, or cheap power during desirable time periods from the grid 262, again for user 266 demands. Other configurations and use cases may be available as well, and the illustrations in FIGS. 5 and 6 are not intended to be limiting.

Batteries 204, 240, and/or 260 may carry, for example, serial numbers allowing ready identification of each. The model data generated in the examples herein may be stored in a form that allows linking of the model data to serial numbers. Doing so will allow the model data to be used in estimating remaining battery capacity if the battery is later re-purposed. Such data can also be used for determining a price for after-market users or resellers. Alternatively, the batteries 204, 240, 260 may have built-in controllers with memory, or standalone memory, on which the model data can be stored.

FIG. 7 is a block flow diagram for an example method for testing or measuring battery capacity. A relaxation period, which may range from minutes to an hour, depending on the battery and prior usage, is enforced at 300. An OCV measurement is obtained at 302. A charge integration event (CIE) occurs at 304. The CIE may be a discharge event or a charging event. In either case, current flow may be monitored out of or into the battery using a current sensor (sometimes called a Coulomb counter) during the CIE. Another relaxation period is enforced at 306, and another OCV measurement is taken at 308. The quantified current during the CIE and the OCV measurements form 302 and 308 can then be used to estimate battery capacity. The process can then be reversed as indicated at 310; that is, if the first CIE at 304 is a charging event, a discharge event may follow or, if the first CIE at 304 is a discharging event, a charging event may follow.

FIGS. 8A-8C show an illustrative example highlighting the decision logic function. Here, a series of battery capacity estimates or measurements are illustrated with line 360. Using the above described methods, two models of battery degradation are populated. A first model of battery degradation generates a prediction as shown with line 350. This first model presumes the battery will degrade in accordance with Formula 1, shown above. At high level, the first model can be described as modeling capacity loss as directly proportional to the square root of time, with an offset. A second model, illustrated by line 352, models capacity using a cubic formula, which presumes an S-shaped curve. Other models may be used.

As shown in the inset 370, in some examples, each of a first error, E1, and a second error, E2, are determined simply as the difference between predicted remaining capacity at a given point in time of each model, relative to the measured or estimated battery capacity 360. If E1, the distance to the degradation model 350 is less than or equal to E2, the distance to the cubic endpoint model 352, then the decision logic uses the degradation model 350 to predict time to end of life of the battery. If E1 is greater than E2, then the decision logic uses the cubic endpoint model to predict time to end of life of the battery. If the system switches from the degradation model to the cubic endpoint model, this may trigger an alert, or diagnostic trouble code, or may otherwise be treated as an event signifying that the battery has been identified as having a foreshortened life.

Other examples may use a different analysis step in the decision logic. For example, the area between line 350 and line 360 may be summed (in signed fashion so that positive and negative excursions cancel each other out, or using absolute values to test variance of the model as desired), as well as the area between line 352 and line 360 in similar fashion. The areas may be compared to determine which model has shown greater accuracy over some period of time; a convergence metric may be used to set a start time for the area calculation. In some examples, a forgetting variable may be used to discount earlier data points as time moves on. In some examples, both a comparison of the models and a comparison of the inverted degradation filter error (E1, or area, etc.) to a fixed threshold may be used, to ensure that the adaptive nature of the cubic end point model does not create erroneous switching between the two models. The decision logic may be designed to assume that the inverted degradation filter is more accurate until the data proves otherwise.

Because both of lines 350 and 352 are based on best fit analyses, what is really being tested by the decision logic is the ability of a “normal” or non-failing model to track incoming data, versus an “abnormal” or failing model. Each provides a very different prediction of end of life time for the battery, with the star at 356 indicating the predicted time of end-of-life using the inverted degradation filter, and star 358 indicating the predicted time of end-of-life using the cubic end point model.

FIG. 8A shows an example at a given point in time—around 1800 days in the Figure. FIG. 8B shows a subsequent point in time for a failing battery. Here, line 360 is extended, and it can be seen that the cubic end point model 352 is fairly close. With the adaptive nature of the cubic end point model 352, there may be some adjustment to line 352 but, in this case, that adjustment would be minor and so is not shown in the drawing. On the other hand, the inverted degradation filter model 350 undergoes changes that are more apparent, as the model is updated with the new data from line 360. Thus line 350 is shifted to position 350′, which also shortens the predicted life as indicated by the shift from 356 to 356′. However, due to the slow-moving design of the inverted degradation filter model 350/350′, the adaptive model cannot keep up with the changing battery capacity due to whatever failure mode has occurred. In this case, the decision logic would respond by identifying the cubic end-point model 352 as the correct predictor of end of life. An alert may issue and the end of life prediction at 358 may be reported to the user, a carrier, a central database, etc.

FIG. 8C shows an alternative to 8B. Here, line 360 is extended, but for a non-failing battery. The inverted degradation filter model represented by line 350 continues to adapt to the new data, though the changes would be minor and are not highlighted in the drawing. On the other hand, the cubic end point model adjusts, as indicated at 352′, as does the predicted end-of-life from 358 to 358′ based on the cubic end-point model.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described.

In the event of inconsistent usages between this document and any documents so incorporated by reference, the usage in this document controls. In this document, the terms “a” or “an” are used, as is common in patent documents, to include one or more than one, independent of any other instances or usages of “at least one” or “one or more.” Moreover, in the claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic or optical disks, magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim. Rather, innovative subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the protection should be determined with reference to the appended claims, along with the full scope of equivalents to which such claims are entitled.

What is claimed is:

1. A method of estimating time to end of life (EOL) for a battery, comprising:
obtaining a plurality of state of charge measurements and current measurements from the battery over a plurality of time points;
estimating battery capacity at each of the plurality of time points;
applying a first model of battery capacity to generate a first set of battery capacity estimates, and estimating a first time to EOL from the first model;
applying a second model of battery capacity to generate a second set of battery capacity estimates, and estimating a second time to EOL from the second model; and
selecting the estimated time to EOL from the first time to EOL and the second time to EOL by determining which of the first set of battery capacity estimates and the second set of battery capacity estimates is more accurate, using the estimated battery capacity for at least one of the time points.

2. The method of claim 1, wherein each of the first model and the second model are adaptive models.

3. The method of claim 1, wherein each of the first model and the second model uses a best fit analysis relative to the estimated battery capacity at each of the plurality of time points.

4. The method of claim 1, wherein the first model is an inverted degradation filter in which the battery capacity is directly proportional to a square root of time.

5. The method of claim 4, wherein the second model is a cubic endpoint model in which the battery capacity is determined from a cubic polynomial using time in the cubic polynomial.

6. The method of claim 4, further comprising using an adaptive model including each of time from first use of the battery, the plurality of battery capacity measurements, and filter parameters to generate each of a gain parameter for the inverted degradation filter, a break-in parameter for the inverted degradation filter, and a plurality of battery capacity estimates;
wherein the step of applying a first model of battery capacity uses the plurality of battery capacity estimates, and
wherein the step of applying a second model of battery capacity uses the plurality of battery capacity estimates.

7. The method of claim 1, wherein the step of selecting the estimated time to EOL is performed by:
determining a first error associated with the first model and a second error associated with the second model; and
identifying the first set of battery capacity estimates as more accurate unless the second error is less than the first error.

8. The method of claim 1, wherein the second model is a cubic endpoint model in which the battery capacity is determined from a cubic polynomial using time in the cubic polynomial.

9. The method of claim 1, further comprising storing data for the first model and the second model as stored data, and associating the stored data with the battery for use in determining a resell price for the battery.

10. The method of claim 1, wherein the first model is a nominal performance model, and the second model is a failing device model, and the step of selecting the estimated time to EOL includes determining that the second model is more accurate, further comprising issuing an alert to a user of the battery in response to determining that the second model is more accurate.

11. A method of estimating time to end of life (EOL) for a battery, comprising:
obtaining a plurality of state of charge and current usage estimates to determine a plurality of battery capacity measurements;
applying an on-board degradation filter using an adaptive model including each of time from first use of the battery, the plurality of battery capacity measurements, and filter parameters to generate each of a gain parameter, a break-in parameter, and a plurality of battery capacity estimates;
applying an inverted degradation filter to estimate a first time to EOL using the gain parameter and the break-in parameter;
applying a cubic end point model to estimate a second time to EOL using the plurality of battery capacity estimates or the plurality of battery capacity measurements;
selecting between the first time to EOL and the second time to EOL using a decision logic.

12. The method of claim 11, further comprising pre-iterating the on-board degradation filter and adaptive model using data from a digital twin by:
reporting the plurality of battery capacity estimates to a server maintaining the digital twin;
receiving estimates of the break-in parameter and the gain parameter from the digital twin; and
determining a correlation matrix for use in the adaptive model from the received estimates of the break-in parameter and the gain parameter from the digital twin.

13. A vehicle comprising:
a motor generator unit (MGU) for providing motive power to the vehicle;
a rechargeable battery configured to provide electric power to the MGU; and
a configurable controller adapted to perform a method of estimating time to end of life (EOL) for a battery, the method comprising:
obtaining a plurality of state of charge measurements and current measurements from the battery over a plurality of time points;
estimating battery capacity at each of the plurality of time points;
applying a first model of battery capacity to generate a first set of battery capacity estimates, and estimating a first time to EOL from the first model;
applying a second model of battery capacity to generate a second set of battery capacity estimates, and estimating a second time to EOL from the second model;
selecting the estimated time to EOL from the first time to EOL and the second time to EOL by determining which of the first set of battery capacity estimates and the second set of battery capacity estimates is more accurate, using the estimated battery capacity for at least one of the time points.

14. The vehicle of claim 13, wherein each of the first model and the second model are adaptive models.

15. The vehicle of claim 13, wherein each of the first model and the second model uses a best fit analysis relative to the estimated battery capacity at each of the plurality of time points.

16. The vehicle of claim 13, wherein the first model is an inverted degradation filter in which the battery capacity is directly proportional to a square root of time.

17. The vehicle of claim 16, wherein the second model is a cubic endpoint model in which the battery capacity is determined from a cubic polynomial using time in the cubic polynomial.

18. The vehicle of claim 16, wherein the controller is further configured to use an adaptive model including each of time from first use of the battery, the plurality of battery capacity measurements, and filter parameters to generate each of a gain parameter for the inverted degradation filter, a break-in parameter for the inverted degradation filter, and a plurality of battery capacity estimates;
wherein the controller is configured to apply the first model of battery capacity using the plurality of battery capacity estimates, and
wherein the controller is configured to apply the second model of battery capacity using the plurality of battery capacity estimates.

19. The vehicle of claim 13, wherein the controller is configured to perform selecting the estimated time to EOL by:
determining a first error associated with the first model and a second error associated with the second model; and
identifying the first set of battery capacity estimates as more accurate unless the second error is less than the first error.

20. The vehicle of claim 13, wherein the first model is a nominal performance model, and the second model is a failing device model, and the controller is configured respond to a determination that the second model is more accurate by issuing an alert to a user of the vehicle.
